(19) United States
(12) Patent Application Publication
(10) Pub. No.: US 2018/0277745 A1
(43) Pub. Date: Sep. 27, 2018

(54) MAGNETIC MEMORY DEVICE

(71) Applicants: TOSHIBA MEMORY CORPORATION, Tokyo (JP); SK HYNIX INC., Icheon-si (KR)

(72) Inventors: Tadaaki OIKAWA, Seoul (KR); Toshihiko NAGASE, Tokyo (JP); Youngmin EEH, Seongnam-si Gyeonggi-do (KR); Daisuke WATANABE, Yokkaichi Mie (JP); Kazuya SAWADA, Seoul (KR); Kenichi YOSHINO, Seoul (KR); Hiroyuki OHTORI, Yokkaichi Mie (JP); Yang Kon KIM, Gyeyang-gu Incheon-si (KR); Ku Youl JUNG, Icheon-si Gyeonggi-do (KR); Jong Koo LIM, Icheon-si Gyeonggi-do (KR); Jae Hyoung LEE, Icheon-si Gyeonggi-do (KR); Soo Man SEO, Icheon-si Gyeonggi-do (KR); Sung Woong CHUNG, Icheon-si Gyeonggi-do (KR); Tae Young LEE, Icheon-si Gyeonggi-do (KR)

(73) Assignees: TOSHIBA MEMORY CORPORATION, Tokyo (JP); SK HYNIX INC., Icheon-si (KR)

(21) Appl. No.: 15/702,677

(22) Filed: Sep. 12, 2017

(30) Foreign Application Priority Data
Mar. 24, 2017 (JP) 2017-058937

(51) Int. Cl. H01L 43/02; H01L 43/08; H01L 43/10; H01L 43/12

(52) U.S. Cl. CPC H01L 43/02; H01L 43/12; H01L 43/10; H01L 43/08

(57) ABSTRACT

According to one embodiment, a magnetic memory device includes a magnetoresistive element, the magnetoresistive element including a first magnetic layer having a variable magnetization direction, a second magnetic layer having a fixed magnetization direction and a nonmagnetic layer provided between the first magnetic layer and the second magnetic layer. The first magnetic layer includes first and second sub-magnetic layers each containing at least iron (Fe) and boron (B), and a concentration of boron (B) contained in the first sub-magnetic layer is different from a concentration of boron (B) contained in the second sub-magnetic layer.

### CROSS-REFERENCE TO RELATED APPLICATIONS

This application is based upon and claims the benefit of priority from Japanese Patent Application No. 2017-058937, filed Mar. 24, 2017, the entire contents of which are incorporated herein by reference.

### FIELD

Embodiments described herein relate generally to a magnetic memory device.

### BACKGROUND

A magnetic memory device (semiconductor integrated circuit device) in which a transistor and a magnetoresistive element are integrated on a semiconductor substrate has been suggested.

The above magnetoresistive element includes a storage layer having a variable magnetization direction, a reference layer having a fixed magnetization direction and a tunnel barrier layer provided between the storage layer and the reference layer.

In the magnetoresistive element, binary data is stored in accordance with the magnetization direction of the storage layer. Thus, it is important to realize a magnetoresistive element comprising an optimized storage layer to obtain an excellent magnetic memory device.

### BRIEF DESCRIPTION OF THE DRAWINGS

FIG. 1 is a cross-sectional view schematically showing the structure of a magnetoresistive element included in each magnetic memory device according to first, second and third embodiments.

FIG. 2 is an explanatory diagram schematically showing a first structural example of a storage layer provided in the magnetoresistive element according to the first embodiment.

FIG. 3 is an explanatory diagram schematically showing a second structural example of the storage layer provided in the magnetoresistive element according to the first embodiment.

FIG. 4 is an explanatory diagram schematically showing a third structural example of the storage layer provided in the magnetoresistive element according to the first embodiment.

FIG. 5 is an explanatory diagram schematically showing a fourth structural example of the storage layer provided in the magnetoresistive element according to the first embodiment.

FIG. 6 is a cross-sectional view schematically showing an example of the general structure of a semiconductor integrated circuit device to which each magnetoresistive element shown in the first, second and third embodiments is applied.

### DETAILED DESCRIPTION

In general, according to one embodiment, a magnetic memory device includes a magnetoresistive element, the magnetoresistive element including a first magnetic layer having a variable magnetization direction, a second magnetic layer having a fixed magnetization direction and a nonmagnetic layer provided between the first magnetic layer and the second magnetic layer, wherein the first magnetic layer includes first and second sub-magnetic layers each containing at least iron (Fe) and boron (B), and a concentration of boron (B) contained in the first sub-magnetic layer is different from a concentration of boron (B) contained in the second sub-magnetic layer.

Embodiments will be described hereinafter with reference to the accompanying drawings.

### Embodiment 1

FIG. 1 is a cross-sectional view schematically showing the structure of a magnetoresistive element included in a magnetic memory device according to a first embodiment. The magnetoresistive element is also called a magnetic tunnel junction (MTJ) element.

The magnetoresistive element 100 shown in FIG. 1 is provided on an underlying structure (not shown). The underlying structure includes a semiconductor substrate, a MOS transistor, an interlayer insulating film, etc. A bottom electrode (not shown) is connected to the lower surface of the magnetoresistive element. The magnetoresistive element 100 is electrically connected to the MOS transistor via the bottom electrode. A top electrode (not shown) is connected to the upper surface of the magnetoresistive element 100. The magnetoresistive element 100 is electrically connected to a bit line (not shown) via the top electrode.

As shown in FIG. 1, the magnetoresistive element 100 includes a buffer layer 10, a storage layer (first magnetic layer) 20, a tunnel barrier layer (nonmagnetic layer) 30, a reference layer (second magnetic layer) 40, an antiferromagnetic layer 50 and a cap layer 60. The storage layer 20 is also called a free layer. The reference layer 10 is also called a pinned layer.

The buffer layer 10 is a layer for controlling the crystallinity and grain size of the storage layer, etc. The buffer layer 10 is formed as, for example, a Ta/Ru layer or a Ta layer.

The storage layer (first magnetic layer) 20 is a ferromagnetic layer having a variable magnetization direction. The magnetization direction of the storage layer 20 is perpendicular to its main surface. The storage layer 20 includes a first sub-magnetic layer 21 and a second sub-magnetic layer 22. The first sub-magnetic layer 21 is in contact with the second sub-magnetic layer 22. Both the first sub-magnetic layer 21 and the second sub-magnetic layer 22 have crystallinity, and contain at least iron (Fe) and boron (B). The first and second sub-magnetic layers 21 and 22 may contain cobalt (Co) in addition to iron (Fe) and boron (B). Specifically, both the first sub-magnetic layer 21 and the second sub-magnetic layer 22 are formed of FeCoB. The concentration of boron (B) contained in the first sub-magnetic layer 11 is different from that in the second sub-magnetic layer 22.

The tunnel barrier layer (nonmagnetic layer) 30 is provided between the storage layer 20 and the reference layer 40, and is in contact with the storage layer 20 and the reference layer 40. The tunnel barrier layer 30 is formed of an insulating material containing magnesium (Mg) and oxygen (O). Specifically, the tunnel barrier layer 30 is formed of MgO. This MgO layer comprises the structure of a body-centered cubic lattice, and has (001) orientation.

The reference layer (second magnetic layer) 40 is a ferromagnetic layer having a fixed magnetization direction. The magnetization direction of the reference layer 40 is perpendicular to its main surface. The reference layer 40 has crystallinity, and contains at least iron (Fe) and boron (B). The reference layer 40 may contain cobalt (Co) in addition to iron (Fe) and boron (B). Specifically, the reference layer 40 is formed of FeCoB.

The antiferromagnetic layer 50 is provided on the reference layer 40, and functions to fix the magnetization direction of the reference layer 40. IrMn is preferably used for the antiferromagnetic layer 50. However, for example, PtMn, NiMn, OsMn, RuMn, RhMn or PdMn may be used for the antiferromagnetic layer 50. Normally, a layer formed of a nonmagnetic element such as ruthenium (Ru) is provided between the reference layer 40 and the antiferromagnetic layer 50 such that the magnetization direction of the reference layer 40 is antiparallel to the magnetization direction of the antiferromagnetic layer 50.

The cap layer 60 is provided on the antiferromagnetic layer 50, and is formed as an Ru layer, a Ta layer, an Ru/Ta/Ru layer, etc.

When the magnetization direction of the storage layer 20 is parallel to the magnetization direction of the reference layer 40 in the above magnetoresistive element 100, the magnetoresistive element 100 is in a low-resistive state. When the magnetization direction of the storage layer 20 is antiparallel to the magnetization direction of the reference layer 40, the magnetoresistive element 100 is in a high-resistive state. Thus, the magnetoresistive element 100 is capable of storing binary data based on the resistive state. The magnetoresistive element 100 is also capable of setting the resistive state, in other words, writing binary data, based on the direction of current flowing in the magnetoresistive element 100.

As described above, in the magnetoresistive element 100 of the present embodiment, the storage layer 20 includes the first sub-magnetic layer 21 and the second sub-magnetic layer 22. Both the first sub-magnetic layer 21 and the second sub-magnetic layer 22 contain at least iron (Fe) and boron (B). It should be noted that, in the present embodiment, the first and second sub-magnetic layers 21 and 22 contain cobalt (Co) in addition to iron (Fe) and boron (B). The concentration of boron (B) contained in the first sub-magnetic layer 21 is different from that in the second sub-magnetic layer 22.

Since the B concentration of the first sub-magnetic layer 21 is different from that of the second sub-magnetic layer 22, the saturation magnetization Ms of the first sub-magnetic layer 21 can be made different from that of the second sub-magnetic layer 22. As result, as described below, it is possible to obtain a magnetoresistive element having excellent characteristics.

To realize better performance of the magnetoresistive element, the improvement of write error rate (WER) is important. To improve the WER, the reduction in saturation magnetization (Ms) is effective. For example, a method for adding a nonmagnetic element to the storage layer to reduce the Ms is known. However, the addition of a nonmagnetic element to reduce the Ms leads to the reduction in perpendicular magnetic anisotropy (K) (anisotropic magnetic field [Hk]). When the saturation magnetization (Ms) is reduced, the magnetoresistive ratio (MR) is also reduced. Thus, a magnetoresistive element is required to prevent the reduction in the MR and K caused by the reduction in the Ms and maintain appropriate MR and K even when the Ms is low.

In the present embodiment, the saturation magnetization (Ms) of the first sub-magnetic layer 21 is made different from that of the second sub-magnetic layer 22 by structuring the storage layer 20 so as to include the first and second sub-magnetic layers 21 and 22 and setting the B concentration of the first sub-magnetic layer 21 so as to be different from than of the second sub-magnetic layer 22. By setting the saturation magnetization (Ms) of the first sub-magnetic layer 21 so as to be different from that of the second sub-magnetic layer 22, it is possible to obtain a magnetoresistive element which can decrease the entire saturation magnetization of the storage layer 20 and prevent the reduction in the MR and Hk. This structure is further explained below.

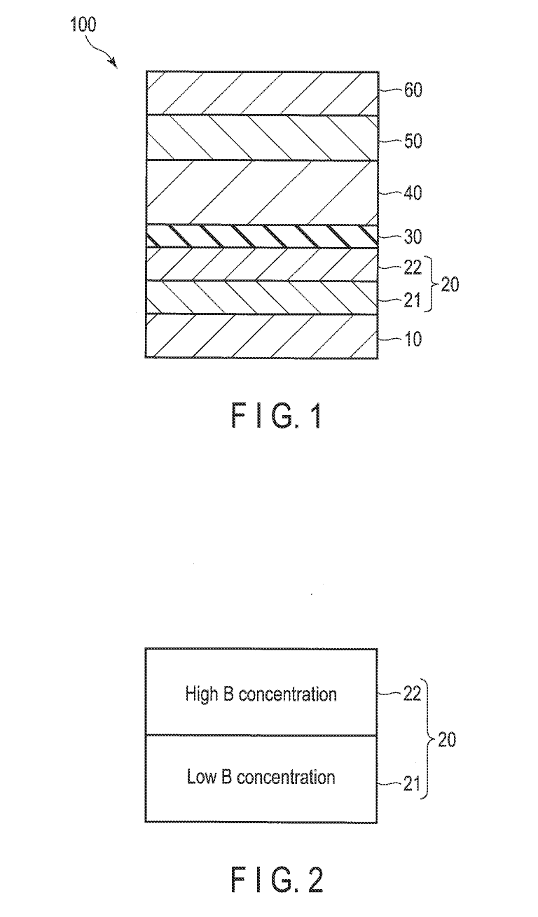

FIG. 2 to FIG. 5 are explanatory diagrams schematically showing first to fourth structural examples of the storage layer 20 (including the first and second sub-magnetic lagers 21 and 22) of the magnetoresistive element of the present embodiment. In all of the first to fourth structural examples, the first and second sub-magnetic layers 21 and 22 are formed of FeCoB.

In the first example shown in FIG. 2, the thickness of the first sub-magnetic layer 21 is the same as that of the second sub-magnetic layer 22. Further, the B concentration of the first sub-magnetic layer 21 is lower than that of the second sub-magnetic layer 22.

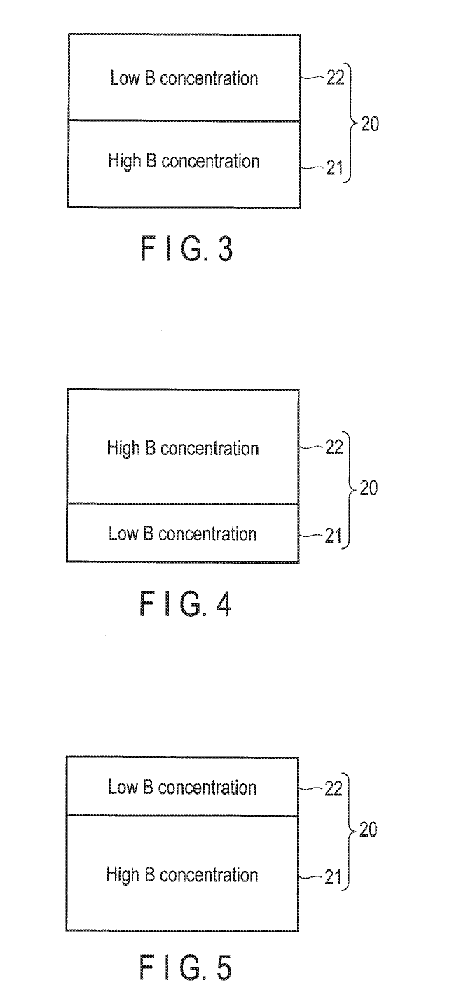

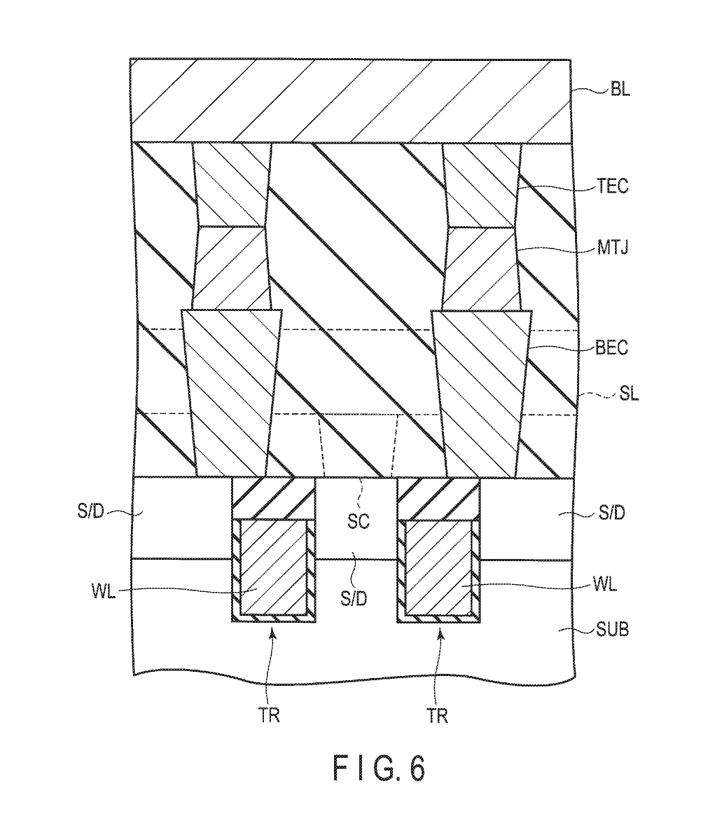

In the second structural example shown in FIG. 3, the thickness of the first sub-magnetic layer 21 is the same as that of the second sub-magnetic layer 22. Further, the B concentration of the first sub-magnetic layer 21 is higher than that of the second sub-magnetic layer 22.

In the third structural example shown in FIG. 4, the first sub-magnetic layer 21 is thinner than the second sub-magnetic layer 22. Further, the B concentration of the first sub-magnetic layer 21 is lower than that of the second sub-magnetic layer 22.

In the fourth structural example shown in FIG. 5, the first sub-magnetic layer 21 is thicker than the second sub-magnetic layer 22. Further, the B concentration of the first sub-magnetic layer 21 is higher than that of the second sub-magnetic layer 22.

In all of the first to fourth structural examples, it is possible to obtain a magnetoresistive element having excellent characteristics by structuring the storage layer 20 so as to include the first and second sub-magnetic layers 21 and 22 and setting the B concentration of the first sub-magnetic layer 21 so as to be different from that of the second sub-magnetic layer 22 in comparison with a case where the storage layer 20 is formed by a single magnetic layer. For example, the actual measurement result shows that both the anisotropic magnetic field (Hk) and the tunnel magnetoresistive ratio (TMR) in the first to fourth structural examples are greater than those in a structure in which the storage layer 20 is formed by a single magnetic layer even when the total film thickness, the average B concentration and the saturation magnetization (Ms) of the entire storage layer in the first to fourth structural examples are the same as those of the structure in which the storage layer 20 is formed by a single magnetic layer. Thus, when the structure of the present embodiment is employed, it is possible to obtain a magnetoresistive element which can improve the anisotropic, magnetic field (Hk) while preventing the reduction in the magnetoresistive ratio (MR) even on condition that the entire saturation magnetization (Ms) of the storage layer 20 is low.

As explained above, both the anisotropic magnetic field (Hk) and the magnetoresistive ratio (MR) in the first to fourth structural examples are greater than those in a structure in which the storage layer 20 is formed by a single magnetic layer. Thus, as long as the B concentration of the first sub-magnetic layer 21 is different from that of the second sub-magnetic layer 22, the B concentration of the first sub-magnetic layer 21 may be either higher or lower than that of the second sub-magnetic layer 22. Similarly, as long as the B concentration of the first sub-magnetic layer 21 is different from that of the second sub-magnetic layer 22, the thickness of the first sub-magnetic layer 21 may be the same as, or greater or less than that of the second sub-magnetic layer 22.

As explained above, it is possible to obtain a magnetoresistive element having excellent characteristics by setting the B concentration of the first sub-magnetic layer 21 so as to be different from that of the second sub-magnetic layer 22, in other words, by setting the saturation magnetization (Ms) of the first sub-magnetic layer 21 so as to be different from that of the second sub-magnetic layer 22. The reasons are analyzed below.

This specification considers a case where the B concentration of the second sub-magnetic layer 22 is higher than that of the first sub-magnetic layer 21, in other words, a case where the saturation magnetization (Ms) of the second sub-magnetic layer 22 is lower than that of the first sub-magnetic layer 21. The magnetoresistive ratio (MR) characteristics are strongly influenced by the state of the interface between the storage layer 20 and the tunnel barrier layer 30. When the B concentration of the second sub-magnetic layer 22 is higher than that of the first sub-magnetic layer 21, a large amount of boron (B) is contained in the second sub-magnetic layer 22. Thus, the amorphous property of the second sub-magnetic layer 22 is relatively high. In this way, the flatness of the interface between the storage layer 20 (second sub-magnetic layer 22) and the tunnel barrier layer 30 is improved, thereby clarifying the interface between the storage layer 20 and the tunnel barrier layer 30. As a result, the continuity of crystal growth is accelerated, and the characteristics of the interface between the storage layer 20 and the tunnel, barrier layer 30 are improved. Further, the magnetoresistive ratio (MR) is improved. When the B concentration of the second sub-magnetic layer 22 is higher than that of the first sub-magnetic layer 21, a small amount of boron (B) is contained in the first sub-magnetic layer 21. Thus, the crystallinity of the first sub-magnetic layer 21 is relatively high. In this way, excellent crystal growth can be conducted. Further, the anisotropic magnetic field (Hk) (perpendicular magnetic anisotropy) can be improved. It is possible to obtain a magnetoresistive element having excellent characteristics.

Now, this specification considers a case where the B concentration of the second sub-magnetic layer 22 is lower than that of the first sub-magnetic layer 21, in other words, a case where the saturation magnetization (Ms) of the second sub-magnetic layer 22 is higher than that of the first sub-magnetic layer 1. In general, the TMR is increased with increasing saturation magnetization (Ms). Thus, when the saturation magnetization (Ms) of the second sub-magnetic layer 22 on the tunnel barrier layer 30 side is great, the TMP of the entire storage layer 20 is also great. In this manner, it is possible to obtain a magnetoresistive element having excellent characteristics.

As explained above, it is possible to obtain a magnetoresistive element having excellent characteristics by setting the B concentration (the concentration of boron) of the first sub-magnetic layer 21 so as to be different from that of the second sub-magnetic layer 22, in other words, by setting the saturation magnetization (Ms) of the first sub-magnetic layer 21 so as to be different from that of the second sub-magnetic layer 22.

### Embodiment 2

Now, this specification explains a magnetic memory device according to a second embodiment. The basic structures of the magnetic memory device and the basic structures of a magnetoresistive element are the same as those of the first embodiment. Explanation of the matters explained in the first embodiment is omitted.

With reference to FIG. 1, the magnetoresistive element included in the magnetic memory device of the present embodiment is explained below.

In a manner similar to that of the magnetoresistive element of the first embodiment, in the magnetoresistive element of the present embodiment, a storage layer (first magnetic layer) 20 includes a first sub-magnetic layer 21 and a second sub-magnetic layer 22. The first sub-magnetic layer 21 is in contact with the second sub-magnetic layer 22. In a manner similar to that of the first embodiment, both the first sub-magnetic layer 21 and the second sub-magnetic layer 22 have crystallinity, and contain at least iron (Fe) and boron (B). The first and second sub-magnetic layers 21 and 22 may contain cobalt (Co) in addition to iron (Fe) and boron (B). Specifically, both the first sub-magnetic layer 21 and the second sub-magnetic layer 22 are formed of FeCoB.

In the present embodiment, both the first sub-magnetic layer 21 and the second sub-magnetic layer 22 contain the same nonmagnetic element (a predetermined nonmagnetic element) in addition to cobalt (Co), iron (Fe) and boron (B). The concentration of the predetermined nonmagnetic element contained in the first sub-magnetic layer 21 is different from that in the second sub-magnetic layer. The predetermined nonmagnetic element is selected from silicon (Si), tantalum (Ta), niobium (Nb), tungsten (W), molybdenum (Mo), chromium (Cr), manganese (Mn) and copper (Cu).

In general, the saturation magnetization (Ms) can be reduced by adding the above nonmagnetic elements to the storage layer. However, as stated in the first embodiment, when the saturation magnetization (Ms) is reduced, the magnetoresistive ratio (MR) is also reduced. Thus, the addition of a nonmagnetic element to reduce the saturation magnetization (Me) leads to the reduction in perpendicular magnetic anisotropy (K) (anisotropic magnetic field [Hk]).

In the present embodiment, in terms of the same factors as the first embodiment, the saturation magnetization (Ms) of the first sub-magnetic layer 21 is made different from that of the second sub-magnetic layer 22 by structuring the storage layer 20 so as to include the first and second sub-magnetic layers 21 and 22 and setting the concentration of the predetermined nonmagnetic element in the first sub-magnetic layer 21 so as to be different from that in the second sub-magnetic layer 22. In this way, it is possible to obtain a magnetoresistive element having excellent characteristics for the same reasons as the first embodiment. Specifically, it is possible to obtain a magnetoresistive element which can prevent the reduction in the MR and Hk while decreasing the entire saturation magnetization (Ms) of the storage layer 20.

In a manner similar to that of the first embodiment, in the present embodiment, as long as the concentration of the predetermined nonmagnetic element in the first sub-magnetic layer 21 is different from that in the second sub-magnetic layer 22, the concentration of the predetermined nonmagnetic element in the first sub-magnetic layer 21 may be either higher or lower than that in the second sub-magnetic layer 22. Similarly, as long as the concentration of the predetermined nonmagnetic element in the first sub-magnetic layer 21 is different from that in the second sub-magnetic layer 22, the thickness of the first sub-magnetic layer 21 may be the same as, or greater or less than that of the second sub-magnetic layer 22.

### Embodiment 3

Now, this specification explains a magnetic memory device according to a third embodiment. The basic structures of the magnetic memory device and the basic structures of a magnetoresistive element are the same as those of the first embodiment. Explanation of the matters explained in the first embodiment is omitted with reference to FIG. 1, the magnetoresistive element included in the magnetic memory device of the present embodiment is explained below.

In a manner similar to that of the magnetoresistive element of the first embodiment, in the magnetoresistive element of the present embodiment, a storage layer (first magnetic layer) 20 includes a first sub-magnetic layer 21 and a second sub-magnetic layer 22. The first sub-magnetic layer 21 is in contact with the second sub-magnetic layer 22. In a manner similar to that of the first embodiment, both the first sub-magnetic layer 21 and the second sub-magnetic layer 22 have crystallinity, and contain at least iron (Fe) and boron (B). The first and second sub-magnetic layers 21 and 22 may contain cobalt (Co) in addition to iron (Fe) and boron (B). Specifically, both the first sub-magnetic layer 21 and the second sub-magnetic layer 22 are formed of FeCoB.

In the present embodiment, one of the first and second sub-magnetic layers 21 and 22 contains a nonmagnetic element (a predetermined nonmagnetic element) which is not contained in the other one of the first and second sub-magnetic layers 21 and 22 in addition to cobalt (Co), iron (Fe) and boron (B). The predetermined nonmagnetic element is selected from silicon (Si), tantalum (Ta), niobium (Nb), tungsten (W), molybdenum (Mo), chromium (Cr), manganese (Mn) and copper (Cu). Specifically, the following two structural examples are considered.

In a first structural example, one of the first and second sub-magnetic layers 21 and 22 contains one of the above predetermined nonmagnetic elements. The other one of the first and second sub-magnetic layers 21 and 22 does not contain any one of the above predetermined nonmagnetic elements.

In a second structural example, one of the first and second sub-magnetic layers 21 and 22 contains a first nonmagnetic element selected from the above predetermined nonmagnetic element. The other one of the first and second sub-magnetic layers 21 and 22 contains a second nonmagnetic element selected from the above predetermined nonmagnetic elements. The first nonmagnetic element is different from the second nonmagnetic element.

In the present embodiment, in a manner similar to that of the first embodiment, the saturation magnetization (Ms) of the first sub-magnetic layer 21 can be made different from that of the second sub-magnetic layer 22. Thus, it is possible to obtain a magnetoresistive element having excellent characteristics for the same reasons explained in the first embodiment. Specifically, it is possible to obtain a magnetoresistive element which can prevent the reduction in the MR while decreasing the entire saturation magnetization (Ms) of the storage layer 20.

In the present embodiment, as long as one of the first and second sub-magnetic layers 21 and 22 contains a predetermined nonmagnetic element which is not contained in the other one of the first and second sub-magnetic layers 21 and 22, the thickness of the first sub-magnetic layer 21 may be the same as, or greater or less than that of the second sub-magnetic layer 22. In the first, second and third embodiments described above, as shown in FIG. 1, the magnetoresistive element 100 is structured such that the storage layer 20, the tunnel barrier layer 30, the reference layer 40 and the antiferromagnetic layer 50 are stacked in this order. However, the antiferromagnetic layer 50, the reference layer 40, the tunnel barrier layer 30 and the storage layer 20 may be stacked in this order.

FIG. 7 is a cross-sectional view schematically showing an example of the general structure of a semiconductor integrated circuit device to which each magnetoresistive element shown in the first, second and third embodiments is applied.

In a semiconductor substrate SUB, a buried-gate MOS transistor TR is formed. The gate electrode of the MOS transistor TR is used as a word line WI. A bottom electrode BEG is connected to one of the source/drain regions S/D of the MOS transistor TR. A source line contact SC is connected to the other one of the source/drain regions S/D.

A magnetoresistive element MTJ is formed on the bottom electrode BEC. A top electrode TEC is formed on the magnetoresistive element MTJ. A bit line at is connected to the top electrode TEC. A source line SL is connected to the source line contact SC.

It is possible to obtain an excellent semiconductor integrated circuit device when each magnetoresistive element explained in the first, second and third embodiments is applied to the semiconductor integrated circuit device shown in FIG. 7.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising a magnetoresistive element, the magnetoresistive element including a first magnetic layer having a variable magnetization direction, a second magnetic layer having a fixed magnetization direction and a nonmagnetic layer provided between the first magnetic layer and the second magnetic layer, wherein
the first magnetic layer includes first and second sub-magnetic layers each containing at least iron (Fe) and boron (B), and
a concentration of boron (B) contained in the first sub-magnetic layer is different from a concentration of boron (B) contained in the second sub-magnetic layer.

2. The magnetic memory device of claim 1, wherein
the first and second sub-magnetic layers further contain cobalt (Co).

3. The magnetic memory device of claim 1, wherein
a saturation magnetization of the first sub-magnetic layer is different from a saturation magnetization of the second sub-magnetic layer.

4. The magnetic memory device of claim 1, wherein
both the first sub-magnetic layer and the second sub-magnetic layer have crystallinity.

5. The magnetic memory device of claim 1, wherein
the first sub-magnetic layer is in contact with the second sub-magnetic layer.

6. The magnetic memory device of claim 1, wherein
the nonmagnetic layer contains magnesium (Mg) and oxygen (O).

7. A magnetic memory device comprising a magnetoresistive element, the magnetoresistive element including a first magnetic layer having a variable magnetization direction, a second magnetic layer having a fixed magnetization direction and a nonmagnetic layer provided between the first magnetic layer and the second magnetic layer, wherein
the first magnetic layer includes first and second sub-magnetic layers each containing at least iron (Fe) and boron (B),
the first and second sub-magnetic layers further contain a same nonmagnetic element, and
a concentration of the nonmagnetic element contained in the first sub-magnetic layer is different from a concentration of the nonmagnetic element contained in the second sub-magnetic layer.

8. The magnetic memory device of claim 7, wherein
the first and second sub-magnetic layers further contain cobalt (Co).

9. The magnetic memory device of- claim 7, wherein
the nonmagnetic element is selected from silicon (Si), tantalum (Ta), niobium (Nb), tungsten (W), molybdenum (Mo), chromium (Cr), manganese (Mn) and copper (Cu).

10. The magnetic memory device of claim 7, wherein
a saturation magnetization of the first sub-magnetic layer is different from a saturation magnetization of the second sub-magnetic layer.

11. The magnetic memory device of claim 7, wherein
both the first sub-magnetic layer and the second sub-magnetic layer have crystallinity.

12. The magnetic memory device of claim 7, wherein
the first sub-magnetic layer is in contact with the second sub-magnetic layer.

13. The magnetic memory device of claim 7, wherein
the nonmagnetic layer contains magnesium (Mg) and oxygen (O).

14. A magnetic memory device comprising a magnetoresistive element, the magnetoresistive element including a first magnetic layer having a variable magnetization direction, a second magnetic layer having a fixed magnetization direction and a nonmagnetic layer provided between the first magnetic layer and the second magnetic layer, wherein
the first magnetic layer includes first and second sub-magnetic layers each containing at least iron (Fe) and boron (B), and
one of the first and second sub-magnetic layers contains a nonmagnetic element which is not contained in the other one of the first and second sub-magnetic layers.

15. The magnetic memory device of claim 14, wherein
the first and second sub-magnetic layers further contain cobalt (Co).

16. The magnetic memory device of claim 14, wherein
the nonmagnetic element is selected from silicon (Si), tantalum (Ta), niobium (Nb), tungsten (W), molybdenum (Mo), chromium (Cr), manganese (Mn) and copper (Cu).

17. The magnetic memory device of claim 14, wherein
a saturation magnetization of the first sub-magnetic layer is different from a saturation magnetization of the second sub-magnetic layer.

18. The magnetic memory device of claim 14, wherein
both the first sub-magnetic layer and the second sub-magnetic layer have crystallinity.

19. The magnetic memory device of claim 14, wherein
the first sub-magnetic layer is in contact with the second sub-magnetic layer.

20. The magnetic memory device of claim 14, wherein
the nonmagnetic layer contains magnesium (Mg) and oxygen (O).
